(19) United States
(12) Patent Application Publication
(10) Pub. No.: US 2010/0302775 A1
(43) Pub. Date: Dec. 2, 2010

(54) LIGHT-EMITTING DEVICE AND DISPLAY

(75) Inventor: Masayuki HATA, Takatsuki-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/726,415

(22) Filed: Mar. 18, 2010

(30) Foreign Application Priority Data
May 27, 2009 (JP) 2009-127250

(51) Int. Cl. F21V 9/00; H01S 5/40; H01L 33/00

(52) U.S. Cl. 362/231; 372/50.121; 257/89; 257/E33.067

(57) ABSTRACT

This light-emitting device includes a waveguide-type red semiconductor light-emitting element emitting a red beam, a waveguide-type green semiconductor light-emitting element emitting a green beam and a waveguide-type blue semiconductor light-emitting element emitting a blue beam, while the width of a waveguide of the semiconductor light-emitting element emitting a beam of a relatively short wavelength is rendered larger than the width of a waveguide of the semiconductor light-emitting element emitting a beam of a relatively long wavelength in at least two semiconductor light-emitting elements among the red semiconductor light-emitting element, the green semiconductor light-emitting element and the blue semiconductor light-emitting element.

### CROSS-REFERENCE TO RELATED APPLICATION

The priority application number JP2009-127250, Light-Emitting Device and Display, May 27, 2009, Masayuki Hata, upon which this patent application is based is hereby incorporated by reference.

### BACKGROUND OF THE INVENTION

1. Field of the Invention

The present invention relates to a light-emitting device and a display, and more particularly, it relates to a light-emitting device and a display each comprising red, green and blue semiconductor laser elements.

2. Description of the Background Art

A display employing laser beams or the like for a light source has recently been actively developed. In particular, employment of semiconductor laser elements as a light source for a small-sized display is expected. In this case, the light source can be further downsized if respective semiconductor laser elements emitting laser beams of red (R), green (G) and blue (B) are loaded on one package.

In general, therefore, a semiconductor light-emitting device loaded with semiconductor laser elements emitting laser beams of red, green and blue is proposed, as disclosed in Japanese Patent Laying-Open No. 2005-129686, for example.

The aforementioned Japanese Patent Laying-Open No. 2005-129686 discloses a triple-wavelength semiconductor laser device (semiconductor light-emitting device) having a blue semiconductor laser element emitting a blue beam in the waveband of 400 nm, a green semiconductor laser element emitting a green beam in the waveband of 500 nm and a red semiconductor laser element emitting a red beam in the waveband of 600 nm formed on the surface of an n-type substrate to transversely align with each other through an insulating layer. The triple-wavelength semiconductor laser device so emits the red beam (R), the green beam (G) and the blue beam (B) corresponding to the three primary colors of light that the same can be utilized as a light source for a full-color display. In the triple-wavelength semiconductor laser device, the only one corresponding semiconductor laser element is provided for each of the three colors.

In order that the full-color display can reproduce ideal white light, the light output powers of the laser elements must be so adjusted that the luminous flux (lumen) ratios of the red, green and blue beams are about 2:about 7:about 1. When employing a red laser beam of about 650 nm, a green laser beam of about 530 nm and a blue laser beam of about 480 nm, for example, ideal white light is realized when a ratio of the laser output powers of the red, green and blue laser beams is adjusted to about 18.7:about 8.1:about 7.1. When employing a red laser beam of about 650 nm, a green laser beam of about 550 nm and a blue laser beam of about 460 nm, on the other hand, ideal white light is realized when a ratio of the laser output powers of the red, green and blue laser beams is adjusted to about 18.7:about 7:about 16.7.

In general, a red semiconductor laser element easily obtains a large laser output power (the obtained output power is large), while green and blue semiconductor laser elements emitting laser beams (in the wavelength range of about 400 nm to about 580 nm) in a shorter wavelength range than the red laser beam (in the wavelength range of about 600 nm to about 800 nm) cannot easily obtain large laser output powers (the obtained output powers are small) as compared with the red semiconductor laser element.

### SUMMARY OF THE INVENTION

A light-emitting device according to a first aspect of the present invention comprises a waveguide-type red semiconductor light-emitting element emitting a red beam, a waveguide-type green semiconductor light-emitting element emitting a green beam and a waveguide-type blue semiconductor light-emitting element emitting a blue beam, while the width of a waveguide of the semiconductor light-emitting element emitting a beam of a relatively short wavelength is rendered larger than the width of a waveguide of the semiconductor light-emitting element emitting a beam of a relatively long wavelength in at least two semiconductor light-emitting elements among the red semiconductor light-emitting element, the green semiconductor light-emitting element and the blue semiconductor light-emitting element.

In the light-emitting device according to the first aspect of the present invention, as hereinabove described, the width of the waveguide of the semiconductor light-emitting element emitting the beam of the relatively short wavelength is rendered larger than the width of the waveguide of the semiconductor light-emitting element emitting the beam of the relatively long wavelength in at least two semiconductor light-emitting elements among the red semiconductor light-emitting element, the green semiconductor light-emitting element and the blue semiconductor light-emitting element. Even if the output power of the semiconductor light-emitting element emitting the beam of the relatively short wavelength is smaller than the output power of the semiconductor light-emitting element emitting the beam of the relatively long wavelength, therefore, not only the semiconductor light-emitting element emitting the beam of the relatively long wavelength but also the semiconductor light-emitting element emitting the beam of the relatively short wavelength can operate at an output power having sufficient light intensity (luminous flux) since the width of the waveguide of the semiconductor light-emitting element emitting the beam of the relatively short wavelength is larger than the width of the waveguide of the semiconductor light-emitting element emitting the beam of the relatively long wavelength. Thus, the light-emitting device can be so formed as to have a laser output power ratio as an ideal white light source, whereby ideal white light can be realized in the light-emitting device formed by combining the semiconductor light-emitting elements oscillating beams of different wavelengths.

In the aforementioned light-emitting device according to the first aspect, an output power of the semiconductor light-emitting element emitting the beam of the relatively short wavelength is preferably smaller than an output power of the semiconductor light-emitting element emitting the beam of the relatively long wavelength. Also when the output power of the green or blue semiconductor light-emitting element emitting the beam of the relatively short wavelength is smaller than the output power of the red semiconductor light-emitting element emitting the beam of the relatively long wavelength, the green or blue semiconductor light-emitting element emitting the beam of a short wavelength can operate at an output power having sufficient light intensity (luminous flux) when the width of the semiconductor light-emitting element emitting the beam of a short wavelength is increased according to the first aspect.

In the aforementioned light-emitting device according to the first aspect, the width of the waveguide of the green semiconductor light-emitting element is preferably rendered larger than the width of the waveguide of the red semiconductor light-emitting element. According to this structure, a green beam of high intensity (luminous flux) can be extracted from the green semiconductor light-emitting element not easily obtaining a prescribed output power as compared with the red semiconductor light-emitting element, whereby ideal white light can be reliably realized.

In the aforementioned light-emitting device according to the first aspect, the width of the waveguide of the blue semiconductor light-emitting element is preferably rendered larger than the width of the waveguide of the red semiconductor light-emitting element. According to this structure, a blue beam of high intensity (luminous flux) can be extracted from the blue semiconductor light-emitting element not easily obtaining a prescribed output power as compared with the red semiconductor light-emitting element, whereby ideal white light can be reliably realized.

In the aforementioned light-emitting device according to the first aspect, the widths of the waveguides of both of the green semiconductor light-emitting element and the blue semiconductor light-emitting element are preferably rendered larger than the width of the waveguide of the red semiconductor light-emitting element. According to this structure, both of the green and blue semiconductor light-emitting elements emitting the beams of relatively short wavelengths as compared with the red semiconductor light-emitting element can operate at output powers having sufficient light intensity (luminous fluxes), whereby ideal white light can be reliably realized in the light-emitting device.

In the aforementioned light-emitting device according to the first aspect, at least one semiconductor light-emitting element among the red semiconductor light-emitting element, the green semiconductor light-emitting element and the blue semiconductor light-emitting element is preferably a ridge-guided semiconductor laser element including a ridge provided on an upper layer on an active layer thereof for constituting the waveguide. In other words, a light-emitting device having a laser output power ratio as an ideal white light source can be easily realized by employing a ridge-guided semiconductor laser element for at least one of light sources of red, green and blue.

In the aforementioned light-emitting device according to the first aspect, the two semiconductor light-emitting elements are preferably ridge-guided semiconductor laser elements including ridges provided on upper layers of active layers thereof for constituting the waveguides, and the width of a bottom portion, closer to the active layer, of the ridge of the semiconductor light-emitting element emitting the beam of the relatively short wavelength is preferably rendered larger than the width of a bottom portion, closer to the active layer, of the ridge of the semiconductor light-emitting element emitting the beam of the relatively long wavelength. In other words, a light-emitting device having a laser output power ratio as an ideal white light source can be easily realized by employing ridge-guided semiconductor laser elements for two light sources having oscillation wavelengths different from each other among light sources of red, green and blue.

In the aforementioned light-emitting device according to the first aspect, at least one semiconductor light-emitting element among the red semiconductor light-emitting element, the green semiconductor light-emitting element and the blue semiconductor light-emitting element is preferably a semiconductor laser element including a current blocking layer, having an opening, provided on the surface of a semiconductor element layer formed on an active layer thereof. In other words, a light-emitting device having a laser output power ratio as an ideal white light source can be easily realized by employing a semiconductor laser element having the aforementioned structure for at least one of light sources of red, green and blue.

In the aforementioned light-emitting device according to the first aspect, the two semiconductor light-emitting elements are preferably semiconductor laser elements including current blocking layers, having openings, provided on the surfaces of semiconductor element layers formed on active layers thereof, and the width of the opening of the current blocking layer of the semiconductor light-emitting element emitting the beam of the relatively short wavelength is preferably rendered larger than the width of the opening of the current blocking layer of the semiconductor light-emitting element emitting the beam of the relatively long wavelength in the two semiconductor light-emitting elements. In other words, a light-emitting device having a laser output power ratio as an ideal white light source can be easily realized by employing semiconductor laser elements having the aforementioned structures for two light sources having oscillation wavelengths different from each other among light sources of red, green and blue.

In the aforementioned light-emitting device according to the first aspect, at least one semiconductor light-emitting element among the red semiconductor light-emitting element, the green semiconductor light-emitting element and the blue semiconductor light-emitting element is preferably a semiconductor laser element having a buried heterostructure (BH structure) whose active layer is held between current blocking layers formed on both side surfaces of the active layer. In other words, a light-emitting device having a laser output power ratio as an ideal white light source can be easily realized by employing a semiconductor laser element having a BH structure for at least one of light sources of red, green and blue.

In the aforementioned light-emitting device according to the first aspect, the two semiconductor light-emitting elements are preferably semiconductor laser elements having BH structures whose active layers are held between current blocking layers formed on both side surfaces of the active layers, and the width of the active layer of the semiconductor light-emitting element emitting the beam of the relatively short wavelength is preferably rendered larger than the width of the active layer of the semiconductor light-emitting element emitting the beam of the relatively long wavelength in the two semiconductor light-emitting elements. In other words, a light-emitting device having a laser output power ratio as an ideal white light source can be easily realized by employing semiconductor laser elements having BH structures for two light sources having oscillation wavelengths different from each other among light sources of red, green and blue.

In the aforementioned light-emitting device according to the first aspect, the red semiconductor light-emitting element, the green semiconductor light-emitting element and the blue semiconductor light-emitting element are preferably arranged in a common package. According to this structure, the light-emitting device can be formed in a state where the three semiconductor light-emitting elements (light-emitting points) are close to each other, whereby the magnitude of a white light source can be reduced due to the light-emitting points close to each other.

In the aforementioned light-emitting device according to the first aspect, the green semiconductor light-emitting element and the blue semiconductor light-emitting element are preferably formed on the surface of a substrate common to the green semiconductor light-emitting element and the blue semiconductor light-emitting element. According to this structure, the two semiconductor light-emitting elements are integrated on the common substrate as compared with a case of forming the green semiconductor light-emitting element and the blue semiconductor light-emitting element on separate substrates and thereafter arranging the three semiconductor light-emitting elements in a package at prescribed intervals, whereby the widths of the integrated semiconductor light-emitting elements can be reduced. Thus, the semiconductor light-emitting elements can be easily arranged in the package.

In the aforementioned light-emitting device having the green semiconductor light-emitting element and the blue semiconductor light-emitting element formed on the surface of the common substrate, the red semiconductor light-emitting element is preferably bonded to at least either the green semiconductor light-emitting element or the blue semiconductor light-emitting element. According to this structure, no space is required for separately arranging the red semiconductor light-emitting element, whereby a space for arranging the semiconductor light-emitting elements can be reduced. Thus, the semiconductor light-emitting elements can be easily arranged in the package.

In this case, at least either the green semiconductor light-emitting element or the blue semiconductor light-emitting element preferably has an active layer on a substrate, and the red semiconductor light-emitting element is preferably bonded to said active-layer side of at least either the green semiconductor light-emitting element or the blue semiconductor light-emitting element. According to this structure, the light-emitting points can be arranged close to each other along the thickness direction of the semiconductor light-emitting elements.

In the aforementioned light-emitting device according to the first aspect, at least one semiconductor light-emitting element among the red semiconductor light-emitting element, the green semiconductor light-emitting element and the blue semiconductor light-emitting element is preferably a semiconductor laser element operating in transverse multimode. According to this structure, a high output power can be easily obtained also in a semiconductor laser element not capable of easily obtaining a prescribed output power, whereby ideal white light can be easily realized.

In this case, the green semiconductor light-emitting element and the blue semiconductor light-emitting element are preferably semiconductor laser elements operating in the transverse multimode, and the red semiconductor light-emitting element is preferably a semiconductor laser element operating in transverse fundamental mode. Also when a semiconductor laser element operating in transverse fundamental mode is employed as the red semiconductor light-emitting element, ideal white light can be easily realized due to the green semiconductor light-emitting element and the blue semiconductor light-emitting element formed by semiconductor laser elements operating in the transverse multimode.

In the aforementioned light-emitting device according to the first aspect, the cavity length of the red semiconductor light-emitting element is preferably larger than the cavity length of at least either the green semiconductor light-emitting element or the blue semiconductor light-emitting element. When the green semiconductor light-emitting element or the blue semiconductor light-emitting element is a nitride-based semiconductor laser element formed by employing a nitride-based semiconductor substrate, the cavity length of the green semiconductor light-emitting element or the blue semiconductor light-emitting element can be reduced according to this structure, whereby the yield of laser elements per substrate can be increased. Thus, the manufacturing cost for the green semiconductor light-emitting element or the blue semiconductor light-emitting element can be reduced. Further, the cavity length of the red semiconductor light-emitting element is larger than the cavity length of the green semiconductor light-emitting element or the blue semiconductor light-emitting element, whereby the output power of the red semiconductor light-emitting element can be easily increased.

A display according to a second aspect of the present invention comprises a light source, including a waveguide-type red semiconductor light-emitting element emitting a red beam, a waveguide-type green semiconductor light-emitting element emitting a green beam and a waveguide-type blue semiconductor light-emitting element emitting a blue beam, so formed that the width of a waveguide of the semiconductor light-emitting element emitting a beam of a relatively short wavelength is rendered larger than the width of a waveguide of the semiconductor light-emitting element emitting a beam of a relatively long wavelength in at least two semiconductor light-emitting elements among the red semiconductor light-emitting element, the green semiconductor light-emitting element and the blue semiconductor light-emitting element, while modulation means modulating the beams emitted from the light source.

As hereinabove described, the display according to the second aspect of the present invention comprises the light source so formed that the width of the waveguide of the semiconductor light-emitting element emitting the beam of the relatively short wavelength is rendered larger than the width of the waveguide of the semiconductor light-emitting element emitting the beam of the relatively long wavelength in at least two semiconductor light-emitting elements among the red semiconductor light-emitting element, the green semiconductor light-emitting element and the blue semiconductor light-emitting element. Even if the output power of the semiconductor light-emitting element emitting the beam of the relatively short wavelength is smaller than the output power of the semiconductor light-emitting element emitting the beam of the relatively long wavelength, therefore, not only the semiconductor light-emitting element emitting the beam of the relatively long wavelength but also the semiconductor light-emitting element emitting the beam of the relatively short wavelength can operate at an output power having sufficient light intensity (luminous flux) since the width of the waveguide of the semiconductor light-emitting element emitting the beam of the relatively short wavelength is larger than the width of the waveguide of the semiconductor light-emitting element emitting the beam of the relatively long wavelength. Thus, the display can be so formed as to have a laser output power ratio as an ideal white light source, whereby ideal white light can be realized in the light-emitting device formed by combining the semiconductor light-emitting elements oscillating beams of different wavelengths.

In the aforementioned display according to the second aspect, at least two semiconductor light-emitting elements among the red semiconductor light-emitting element, the green semiconductor light-emitting element and the blue semiconductor light-emitting element are preferably arranged in packages separate from each other. Even if an optical system in a state where light sources of red, green and blue have different optical paths is formed in the display, the optical system can be simplified according to this structure. Thus, the degree of freedom in design of the optical system in the display can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the structure of a semiconductor laser device according to a first embodiment of the present invention;

FIG. 2 is a sectional view detailedly showing the structure of the semiconductor laser device according to the first embodiment shown in FIG. 1;

FIGS. 3 and 4 are schematic diagrams of projectors each loaded with the semiconductor laser device according to the first embodiment of the present invention;

FIGS. 5 to 7 are schematic diagrams of projectors each loaded with a semiconductor laser device according to a second embodiment of the present invention;

FIG. 8 is a plan view showing the structure of a semiconductor laser device according to a third embodiment of the present invention;

FIG. 9 is a sectional view detailedly showing the structure of the semiconductor laser device according to the third embodiment shown in FIG. 8;

FIG. 10 is a plan view showing the structure of a semiconductor laser device according to a fourth embodiment of the present invention;

FIG. 11 is a sectional view taken along the line 4000-4000 in FIG. 10;

FIG. 12 is a sectional view taken along the line 4100-4100 in FIG. 10; and

FIG. 13 is a plan view of the semiconductor laser device according to the fourth embodiment shown in FIG. 10, from which a red semiconductor laser element is removed.

### DESCRIPTION OF THE PREFERRED EMBODIMENTS

Embodiments of the present invention are now described with reference to the drawings.

### First Embodiment

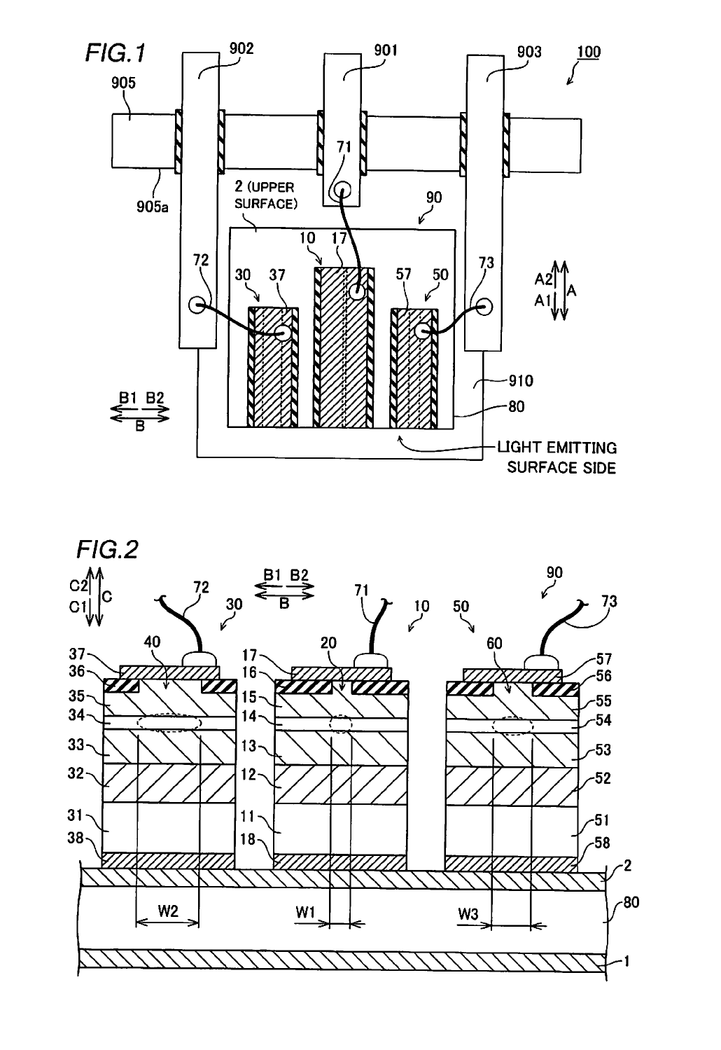

The structure of a semiconductor light-emitting device 100 according to a first embodiment of the present invention is now described with reference to FIGS. 1 and 2. The semiconductor light-emitting device 100 is an example of the “light source” in the present invention.

In the semiconductor light-emitting device 100 according to the first embodiment of the present invention, an RGB triple-wavelength semiconductor laser element portion 90 is fixed onto the upper surface of a protruding block 910 through a conductive adhesive layer 1 (see FIG. 2) of AuSn solder or the like, as shown in FIG. 1. In the RGB triple-wavelength semiconductor laser element portion 90, a red semiconductor laser element 10 having an oscillation wavelength of about 655 nm, a green semiconductor laser element 30 having an oscillation wavelength of about 530 nm and a blue semiconductor laser element 50 having an oscillation wavelength of about 480 nm are fixed onto the upper surface of a base 80 through a conductive adhesive layer 2 of AuSn solder or the like at prescribed intervals along a direction B, as shown in FIG. 2. The red semiconductor laser element 10, the green semiconductor laser element 30 and the blue semiconductor laser element 50 are examples of the “red semiconductor light-emitting element”, the “green semiconductor light-emitting element” and the “blue semiconductor light-emitting element” in the present invention respectively. The red semiconductor laser element 10, the green semiconductor laser element 30 and the blue semiconductor laser element 50 are formed as broad stripe semiconductor laser elements oscillating laser beams in transverse multimode.

In order to obtain white light with the RGB triple-wavelength semiconductor laser element portion 90, the output power ratios of the three semiconductor laser elements, i.e., the aforementioned red, green and blue semiconductor laser elements 10, 30 and 50 of 655 nm, 530 nm and 480 nm must be adjusted to about 24.5:about 8.1:about 7.2 in terms of watts (corresponding to luminous flux (lumen) ratios of about 2:about 7:about 1). In other words, the red semiconductor laser element 10, the green semiconductor laser element 30 and the blue semiconductor laser element 50 are so formed as to have rated output powers of about 2500 mW, about 800 mW and about 700 mW respectively according to the first embodiment.

According to the first embodiment, the red semiconductor laser element 10 is so formed that a waveguide (region surrounded by a broken line in FIG. 2) formed in a semiconductor element layer (portion of an active layer 14) has a width W1 of about 5 μm while the green semiconductor laser element 30 and the blue semiconductor laser element 50 are so formed that waveguides (regions surrounded by broken lines) formed therein have a width W2 of about 20 μm and a width W3 of about 10 μm respectively, as shown in FIG. 2. In other words, the widths (W2 and W3) of the waveguides in the green semiconductor laser element 30 and the blue semiconductor laser element 50 having the oscillation wavelengths smaller than that of the red semiconductor laser element 10 are rendered larger than the width W1 of the waveguide of the red semiconductor laser element 10 (W1<W2 and W1<W3).

In the red semiconductor laser element 10, an n-type buffer layer 12 made of Si-doped GaAs, an n-type cladding layer 13 made of Si-doped AlGaInP, a multiple quantum well (MQW) active layer 14 formed by alternately stacking AlGaInP barrier layers and GaInP well layers and a p-type cladding layer 15 made of Zn-doped AlGaInP are formed on the surface of an n-type GaAs substrate 11, as shown in FIG. 2.

The p-type cladding layer 15 has a projecting portion and planar portions extending on both sides (in the direction B) of the projecting portion. The projecting portion of the p-type cladding layer 15 forms a ridge 20 for constituting the waveguide having the width W1 (about 5 μm) in the portion of the active layer 14. The width of the bottom portion (closer to the active layer 14) of the ridge 20 corresponds to the width W1 of the waveguide. A current blocking layer 16 made of SiO₂ is formed to cover portions of the upper surface of the p-type cladding layer 15 other than the ridge 20. A p-side pad electrode 17 made of Au or the like is formed to cover the upper surfaces of the ridge 20 and the current blocking layer 16. A contact layer or an ohmic electrode layer preferably having a smaller band gap than the p-type cladding layer 15 may be formed between the ridge 20 and the p-side pad electrode 17. An n-side electrode 18 constituted of an AuGe layer, an Ni layer and an Au layer successively stacked from the side closer to the n-type GaAs substrate 11 is formed on the lower surface of the n-type GaAs substrate 11.

In the green semiconductor laser element 30, an n-type GaN layer 32 made of Ge-doped GaN, an n-type cladding layer 33 made of n-type AlGaN, an MQW active layer 34 formed by alternately stacking quantum well layers and barrier layers of InGaN and a p-type cladding layer 35 made of p-type AlGaN are formed on the upper surface of an n-type GaN substrate 31, as shown in FIG. 2.

The p-type cladding layer 35 has a projecting portion and planar portions extending on both sides (in the direction B) of the projecting portion. The projecting portion of the p-type cladding layer 35 forms a ridge 40 for constituting the waveguide having the width W2 (about 20 μm) in the portion of the active layer 34. The width of the bottom portion (closer to the active layer 34) of the ridge 40 corresponds to the width W2 of the waveguide. A current blocking layer 36 made of SiO₂ is formed to cover portions of the upper surface of the p-type cladding layer 35 other than the ridge 40. A p-side pad electrode 37 made of Au or the like is formed to cover the upper surfaces of the ridge 40 and the current blocking layer 36. A contact layer or an ohmic electrode layer preferably having a smaller band gap than the p-type cladding layer 35 may be formed between the ridge 40 and the p-side pad electrode 37. An n-side electrode 38 constituted of a Ti layer, a Pt layer and an Au layer successively stacked from the side closer to the n-type GaN substrate 31 is formed on the lower surface of the n-type GaN substrate 31.

In the blue semiconductor laser element 50, an n-type GaN layer 52 made of Ge-doped GaN, an n-type cladding layer 53 made of n-type AlGaN, an MQW active layer 54 formed by alternately stacking quantum well layers and barrier layers of InGaN and a p-type cladding layer 55 made of p-type AlGaN are formed on the upper surface of an n-type GaN substrate 51, as shown in FIG. 2.

The p-type cladding layer 55 has a projecting portion and planar portions extending on both sides (in the direction B) of the projecting portion. The projecting portion of the p-type cladding layer 55 forms a ridge 60 for constituting the waveguide having the width W3 (about 10 μm) in the portion of the active layer 54. The width of the bottom portion (closer to the active layer 54) of the ridge 60 corresponds to the width W3 of the waveguide. A current blocking layer 56 made of SiO₂ is formed to cover portions of the upper surface of the p-type cladding layer 55 other than the ridge 60. A p-side pad electrode 57 made of Au or the like is formed to cover the upper surfaces of the ridge 60 and the current blocking layer 56. A contact layer or an ohmic electrode layer preferably having a smaller band gap than the p-type cladding layer 55 may be formed between the ridge 60 and the p-side pad electrode 57. An n-side electrode 58 constituted of a Ti layer, a Pt layer and an Au layer successively stacked from the side closer to the n-type GaN substrate 51 is formed on the lower surface of the n-type GaN substrate 51.

According to the first embodiment, the cavity length (in a direction A) of the red semiconductor laser element 10 is rendered larger than both of the cavity lengths (in the direction A) of the green semiconductor laser element 30 and the blue semiconductor laser element 50, as shown in FIG. 1.

As shown in FIG. 1, the semiconductor light-emitting device 100 comprises a stem 905 provided with the protruding block 910 loaded with the RGB triple-wavelength semiconductor laser element portion 910, three lead terminals 901, 902 and 903 electrically insulated from the protruding block 910 while passing through a bottom portion 905a and a cathode lead terminal (not shown) electrically conducting with the protruding block 910 and the bottom portion 905a.

The red semiconductor laser element 10 is connected to the lead terminal 901 through a metal wire 71 bonded to the p-side pad electrode 17 (see FIG. 2). The green semiconductor laser element 30 is connected to the lead terminal 902 through a metal wire 72 bonded to the p-side pad electrode 37 (see FIG. 2). The blue semiconductor laser element 50 is connected to the lead terminal 903 through a metal wire 73 boned to the p-side pad electrode 57 (see FIG. 2).

The base 80 loaded with the semiconductor laser elements (10, 30 and 50) is made of a conductive material such as AlN, and electrically connected to the protruding block 910 through the conductive adhesive layer 1. Thus, the semiconductor light-emitting device 100 is in a state (cathode-common state) where the p-side electrodes (17, 37 and 57) of the semiconductor laser elements (10, 30 and 50) are connected to the lead terminals (901, 902 and 903) insulated from each other while the n-side electrodes (18, 38 and 58) are connected to the common cathode lead terminal (not shown).

In the red semiconductor laser element 10, the green semiconductor laser element 30 and the blue semiconductor laser element 50, light emitting surfaces (A1 side in FIG. 1) and light reflecting surfaces (A2 side in FIG. 1) are formed on both end portions in a cavity direction. Dielectric multilayer film having low reflectance is formed on each of the light emitting surfaces of the semiconductor laser elements 10, 30 and 50, while dielectric multilayer film having high reflectance is formed on each of the light reflecting surfaces. Multilayer stacks of GaN, AlN, BN, Al₂O₃, SiO₂, ZrO₂, Ta₂O₃, Nb₂O₅, La₂O₃, SiN, AlON, MgF₂, Ti₃O₅, Nb₂O₃ and so on can be used as the dielectric multilayer films.

In the red semiconductor laser element 10, the green semiconductor laser element 30 and the blue semiconductor laser element 50, optical guiding layers or carrier blocking layers may be formed between the n-type cladding layer and the active layer. Further, a contact layer or the like may be formed on the opposite side of the n-type cladding layer to the active layer side. In addition, optical guiding layers or carrier blocking layer may be formed between the active layer and the p-type cladding layer. Further, a contact layer or the like may be formed on the opposite side of the p-type cladding layer to the active-layer side. The active layer may be formed by single layer, or may have a single quantum well structure or the like.

A manufacturing process for the semiconductor light-emitting device 100 according to the first embodiment is now described with reference to FIGS. 1 and 2.

In the manufacturing process for the semiconductor light-emitting device 100 according to the first embodiment, the n-type buffer layer 12, the n-type cladding layer 13, the active layer 14 and the p-type cladding layer 15 are successively formed on the upper surface of the n-type GaAs substrate 11 by metal organic vapor phase epitaxy, as shown in FIG. 2. Thereafter a resist pattern is formed on the upper surface of the p-type cladding layer 15 by photolithography and thereafter employed as a mask for performing dry etching or the like, thereby forming the ridge 20 (projecting portion) on the p-type cladding layer 15.

At this time, the ridge 20 is so formed that the waveguide having the width W1 of about 5 μm is formed in the portion of the active layer 14 according to the first embodiment.

Thereafter the current blocking layer 16 is formed to cover the upper surfaces of the planar portions of the p-type cladding layer 15 other than the projecting portion and both side surfaces of the ridge 20. Then, the p-side pad electrode 17 is formed on the current blocking layer 16 and the portion of the p-type cladding layer 15 not provided with the current blocking layer 16 by vacuum evaporation. Then, the lower surface of the n-type GaAs substrate 11 is polished, and the n-side electrode 18 is thereafter formed on the lower surface of the n-type GaAs substrate 11, thereby preparing a wafer of the red semiconductor laser element 10. Thereafter the wafer is cleaved in the form of a bar to have a prescribed cavity length and divided (brought into a chip state) in the cavity direction, thereby forming a chip of the red semiconductor laser element 10 (see FIG. 1).

Chips of the green semiconductor laser element 30 and the blue semiconductor laser element 50 are formed similarly to the chip of the aforementioned red semiconductor laser element 10. The ridge 40 is so formed that the waveguide having the width W2 of about 20 μm is formed in the portion of the active layer 34 when the green semiconductor laser element 30 is formed, while the ridge 60 is so formed that the waveguide having the width W3 of about 10 μm is formed in the portion of the active layer 54 when the blue semiconductor laser element 50 is formed.

Thereafter the RGB triple-wavelength semiconductor laser element portion 90 is formed by fixing the red semiconductor laser element 10, the green semiconductor laser element 30 and the blue semiconductor laser element 50 to the base 80 through the conductive adhesive layer 2 while pressing the former against the latter with a collet (not shown) of ceramics. Thereafter the RGB triple-wavelength semiconductor laser element portion 90 is bonded to the protruding block 910 provided on the stem 905 through the conductive adhesive layer 1 while pressing the former against the latter. Thus, the base 80 is electrically connected to the cathode lead terminal through the protruding block 910.

Thereafter the p-side pad electrode 17 of the red semiconductor laser element 10 and the lead terminal 901 are connected with each other by the metal wire 71, as shown in FIG. 1. Further, the p-side pad electrode 37 of the green semiconductor laser element 30 and the lead terminal 902 are connected with each other by the metal wire 72. In addition, the p-side pad electrode 57 of the blue semiconductor laser element 50 and the lead terminal 903 are connected with each other by the metal wire 73. Thus, the semiconductor light-emitting device 100 according to the first embodiment is formed.

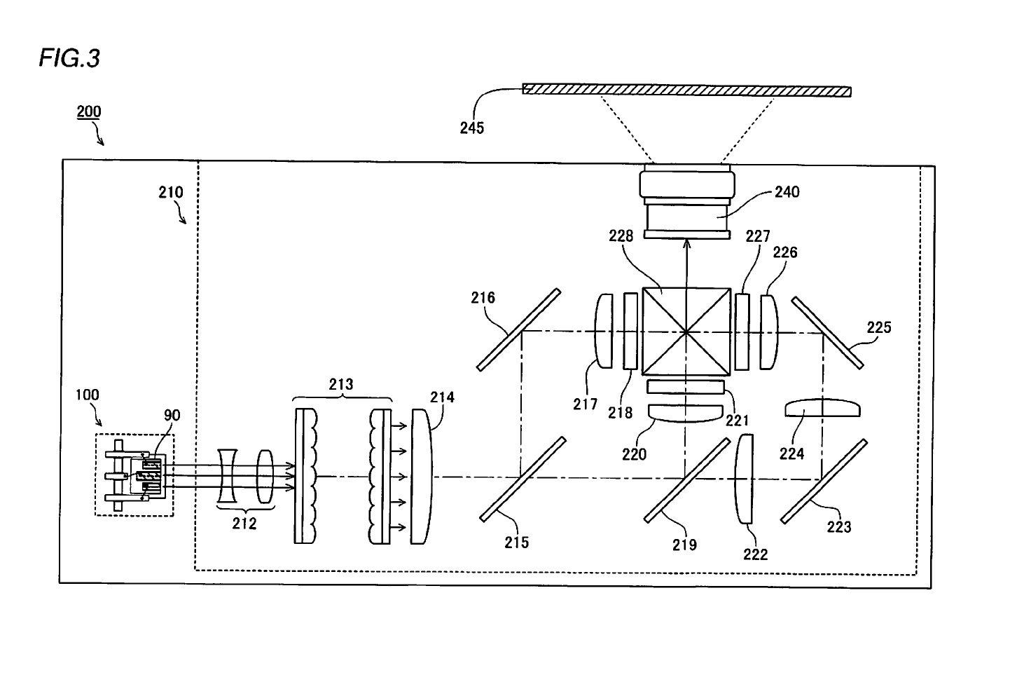

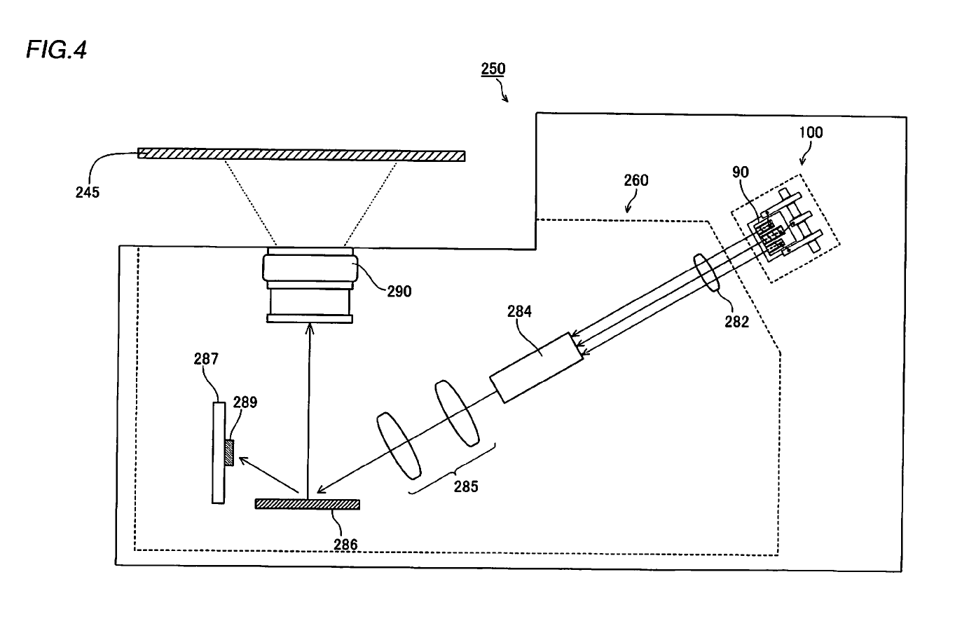

The structures of projectors 200 and 250 each loaded with the semiconductor light-emitting device 100 according to the first embodiment of the present invention are now described with reference to FIGS. 3 and 4. The projectors 200 and 250 are examples of the “display” in the present invention.

As shown in FIG. 3, the projector 200 comprises the semiconductor light-emitting device 100 mounted with the RGB triple-wavelength semiconductor laser element portion 90 and an optical system 210 consisting of a plurality of optical components. Thus, the projector 200 is so formed that laser beams emitted from the semiconductor light-emitting device 100 are modulated by the optical system 210 and thereafter projected on an external screen 245 or the like. The optical system 210 is an example of the “modulation means” in the present invention.

In the optical system 210, the laser beams emitted from the semiconductor light-emitting device 100 are converted to parallel beams having prescribed beam diameters by a dispersion-angle-control lens assembly 212 consisting of a convex lens and a concave lens, and thereafter introduced into a fly-eye integrator 213. The fly-eye integrator 213 is so formed that two fly-eye lenses consisting of fly-eye lens groups face each other, and provides a lens function to the beams introduced from the dispersion-angle-control lens assembly 212 for uniformizing distributions of the quantities of the beams incident upon liquid crystal panels 218, 221 and 227. In other words, the beams transmitted through the fly-eye integrator 213 are controlled to be incident upon the liquid crystal panels 218, 221 and 227 with spreading of an aspect ratio (16:9, for example) corresponding to the sizes thereof.

A condenser lens 214 condenses the beams transmitted through the fly-eye integrator 213. A dichroic mirror 215 reflects only a red beam among the beams transmitted through the fly-eye integrator 213, while transmitting green and blue beams.

The red beam passes through a mirror 216 and is introduced into the liquid crystal panel 218 after parallelization by a lens 217. The liquid crystal panel 218 is driven in response to a driving signal for red, and modulates the red beam in response to the driven state thereof. The red beam transmitted through the lens 217 is introduced into the liquid crystal panel 218 through an incidence-side polarizing plate (not shown).

A dichroic mirror 219 reflects only the green beam in the beams transmitted through the dichroic mirror 215, while transmitting the blue beam.

The green beam is parallelized by a lens 220 and thereafter introduced into the liquid crystal panel 221. The liquid crystal panel 221 is driven in response to a driving signal for green, and modulates the green beam in response to the driven state thereof. The green beam transmitted through the lens 220 is introduced into the liquid crystal panel 221 through an incidence-side polarizing plate (not shown).

The blue beam transmitted through the dichroic mirror 219 passes through a lens 222, a mirror 223, a lens 224 and a mirror 225, is parallelized by a lens 226, and thereafter introduced into the liquid crystal panel 227. The liquid crystal panel 227 is driven in response to a driving signal for blue, and modulates the blue beam in response to the driven state thereof. The blue beam transmitted through the lens 226 is introduced into the liquid crystal panel 227 through an incidence-side polarizing plate (not shown).

Thereafter a dichroic prism 228 synthesizes the red, green and blue beams modulated by the liquid crystal panels 218, 221 and 227 and passing through an outgoing-side polarizing plate (not shown) and introduces the same into a projection lens 240. The projection lens 240 stores a lens group for imaging projection light on a projected surface (screen 245) and an actuator for adjusting the zoom and the focus of projected images by displacing some lenses of the lens group in an optical axis direction. The projector 200 loaded with the semiconductor light-emitting device 100 according to the first embodiment of the present invention is constituted in this manner.

As shown in FIG. 4, on the other hand, the projector 250 comprises the semiconductor light-emitting device 100 mounted with the RGB triple-wavelength semiconductor laser element portion 90 and an optical system 260. Thus, the projector 250 is so formed that laser beams from the semiconductor light-emitting device 100 are modulated by the optical system 260 and thereafter projected on a screen 245 or the like. The optical system 260 is an example of the “modulation means” in the present invention.

In the optical system 260, each of the laser beams emitted from the semiconductor light-emitting device 100 is converted to a parallel beam by a lens 282, and thereafter introduced into a light pipe 284.

The light pipe 284 has a mirror-finished inner surface, and each of the laser beams is reflected on the inner surface of the light pipe 284 again and again while advancing therein. At this time, intensity distributions of the laser beams of the respective colors emitted from the light pipe 284 are uniformized due to multireflection in the light pipe 284. The laser beams emitted from the light pipe 284 are introduced into a digital micromirror device (DMD) 286 through a relay optical system 285.

The DMD 286 has a function of expressing gradations of respective pixels by switching light reflecting directions on respective pixel positions between a first direction toward a projection lens 290 and a second direction deviating from the projection lens 290. Among the laser beams introduced into the respective pixel positions, each beam (ON-beam) reflected in the first direction is introduced into the projection lens 290 and projected on a projected surface (screen 245). On the other hand, each beam (OFF-beam) reflected in the second direction by the DMD 286 is not introduced into the projection lens 290 but absorbed by a light absorber 287.

The optical system 260 is so formed as to drive red, green and blue laser beam sources constituting the semiconductor light-emitting device 100 in a time-divided manner every color. In other words, the DMD 286 is driven in response to a driving signal for red at timing when the red beam is emitted, and modulates the red beam in response to the driven state thereof. Similarly, the DMD 286 is driven in response to a driving signal for green or blue at timing when the green or blue beam is emitted, and modulates the green or blue beam in response to the driven state thereof. The projector 250 loaded with the semiconductor light-emitting device 100 according to the first embodiment of the present invention is constituted in this manner.

According to the first embodiment, as hereinabove described, both of the widths W2 and W3 of the waveguides of the green and blue semiconductor laser elements 30 and 50 are rendered larger than the width W1 of the waveguide of the red semiconductor laser element 10. Even if the output powers of the green and blue semiconductor laser elements 30 and 50 are smaller than the output power of the red semiconductor laser element 10, therefore, not only the red semiconductor laser element 10 but also the green and blue semiconductor laser elements 30 and 50 can operate at laser output powers having sufficient light intensity (luminous fluxes) since the widths W2 and W3 of the waveguides of the green and blue semiconductor laser elements 30 and 50 are larger than the width W1 of the waveguide of the red semiconductor laser element 10. Thus, the semiconductor light-emitting device 100 can be so formed as to have a laser output power ratio as an ideal white light source, whereby ideal white light can be realized in the semiconductor light-emitting device 100.

According to the first embodiment, the width W2 of the waveguide of the green semiconductor laser element 30 is rendered larger than the width W1 of the waveguide of the red semiconductor laser element 10 so that a green beam of high intensity (luminous flux) can be extracted from the green semiconductor laser element 30 not easily obtaining a prescribed output power as compared with the red semiconductor laser element 10, whereby the semiconductor light-emitting device 100 can reliably realize ideal white light.

According to the first embodiment, the width W3 of the waveguide of the blue semiconductor laser element 50 is rendered larger than the width W1 of the waveguide of the red semiconductor laser element 10 so that a blue beam of high intensity (luminous flux) can be extracted from the blue semiconductor laser element 50 not easily obtaining a prescribed output power as compared with the red semiconductor laser element 10, whereby the semiconductor light-emitting device 100 can reliably realize ideal white light.

According to the first embodiment, the red, green and blue semiconductor laser elements 10, 30 and 50 are so arranged on the upper surface of the base 80 that the semiconductor light-emitting device 100 can be formed in a state where the three semiconductor laser elements 10, 30 and 50 (light-emitting points) are close to each other along the direction B, whereby the magnitude of a white light source can be reduced due to the light-emitting points close to each other.

According to the first embodiment, the red semiconductor laser element 10 is arranged on the upper surface of the base 80 to be held between the green and blue semiconductor laser elements 30 and 50 so that the respective colors can be easily mixed with each other due to the red light-emitting point, which has the narrowest optical waveguide, held between the green and blue light-emitting points, whereby a uniform white light source can be obtained.

According to the first embodiment, the green and blue semiconductor laser elements 30 and 50 are so formed by broad stripe semiconductor laser elements that output powers can be easily increased also in these semiconductor laser elements 30 and 50 not easily obtaining prescribed output powers, whereby ideal white light can be easily realized due to the increased output powers.

According to the first embodiment, the cavity length of the red semiconductor laser element 10 is rendered larger than those of the green and blue semiconductor laser elements 30 and 50 so that the cavity lengths of the green and blue semiconductor laser elements 30 and 50 which are nitride-based semiconductor laser elements formed on the n-type GaN substrates 31 and 51 can be reduced, whereby the yield of laser element chips per substrate can be increased. Thus, the manufacturing costs for the green and blue semiconductor laser elements 30 and 50 can be reduced. Further, the cavity length of the red semiconductor laser element 10 is larger than that of the green semiconductor laser element 30 (blue semiconductor laser element 50), whereby the output power of the red semiconductor laser element 10 can be easily increased.

### Second Embodiment

A second embodiment of the present invention is described with reference to FIGS. 3 to 7. According to the second embodiment, semiconductor laser elements identical to those employed in the aforementioned first embodiment are loaded in a projector in a state not mounted in the same package, dissimilarly to the aforementioned first embodiment.

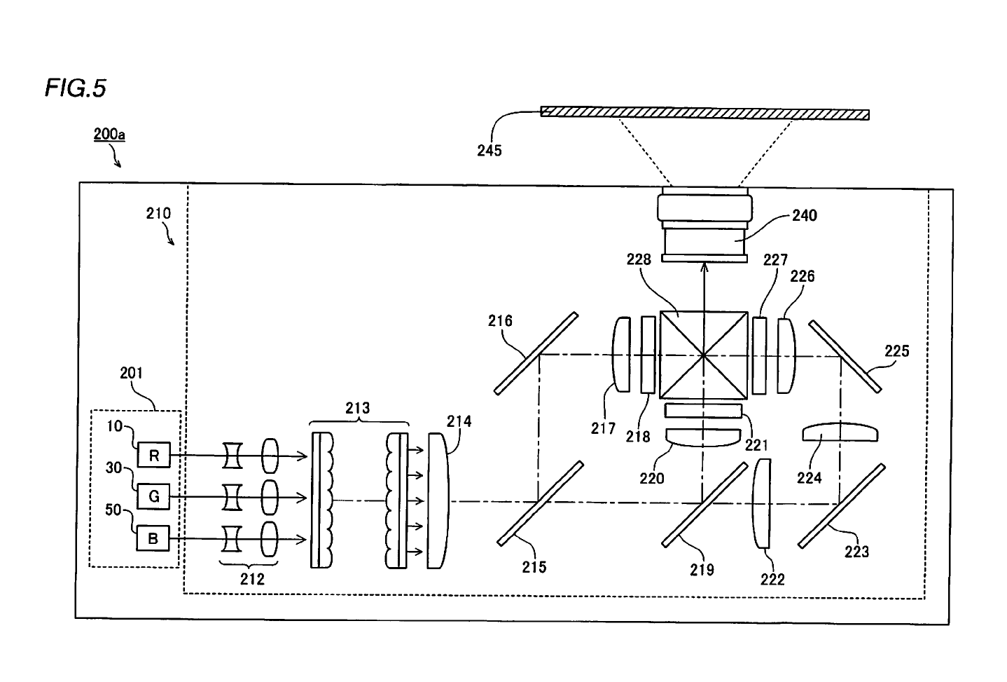

In a projector 200a shown in FIG. 5, a red semiconductor laser element 10, a green semiconductor laser element 30 and a blue semiconductor laser element 50 provided in packages separate from each other are arrayed to constitute a light source portion 201. Laser beams emitted from the semiconductor laser elements 10, 30 and 50 are modulated by the optical system 210 of the projector 200 (see FIG. 3) in the aforementioned first embodiment, and thereafter projected on an external screen 245 or the like. The projector 200a is an example of the “display” in the present invention.

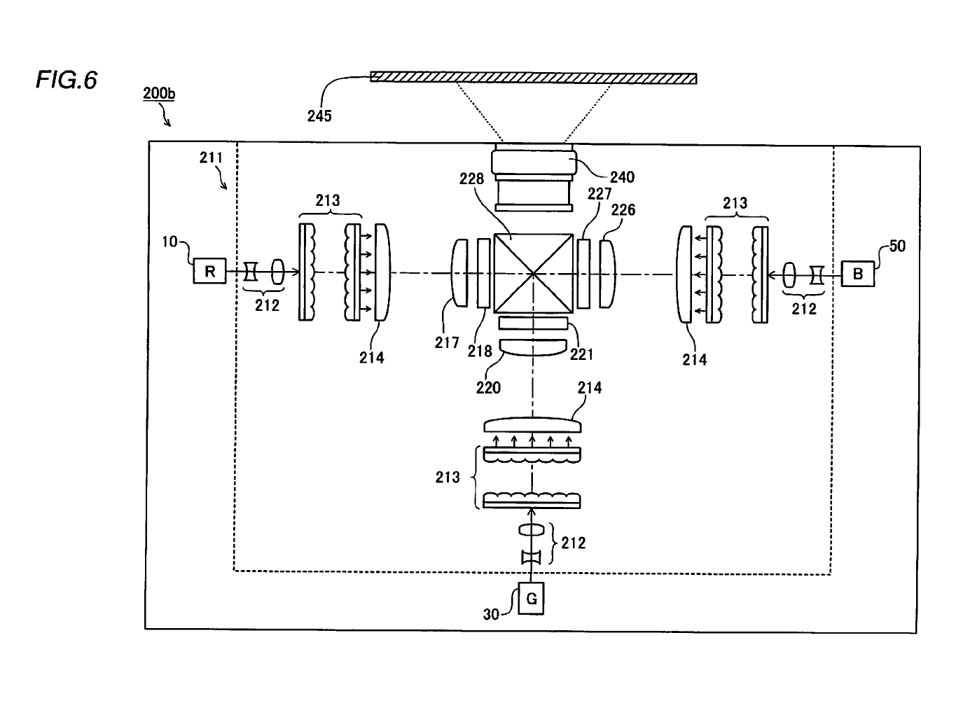

In a projector 200b shown in FIG. 6, an optical system 211 prepared by changing the layout of the optical system 210 (see FIG. 5) is so formed as to project laser beams emitted from a red semiconductor laser element 10, a green semiconductor laser element 30 and a blue semiconductor laser element 50 arranged in separate packages (on different light-emitting positions) on a screen 245. In this case, respective dispersion-angle-control lens assemblies 212, respective fly-eye integrators 213 and respective condenser lenses 214 are employed for light sources of red, green and blue. The projector 200b is an example of the “display” in the present invention, and the optical system 211 is an example of the “modulation means” in the present invention.

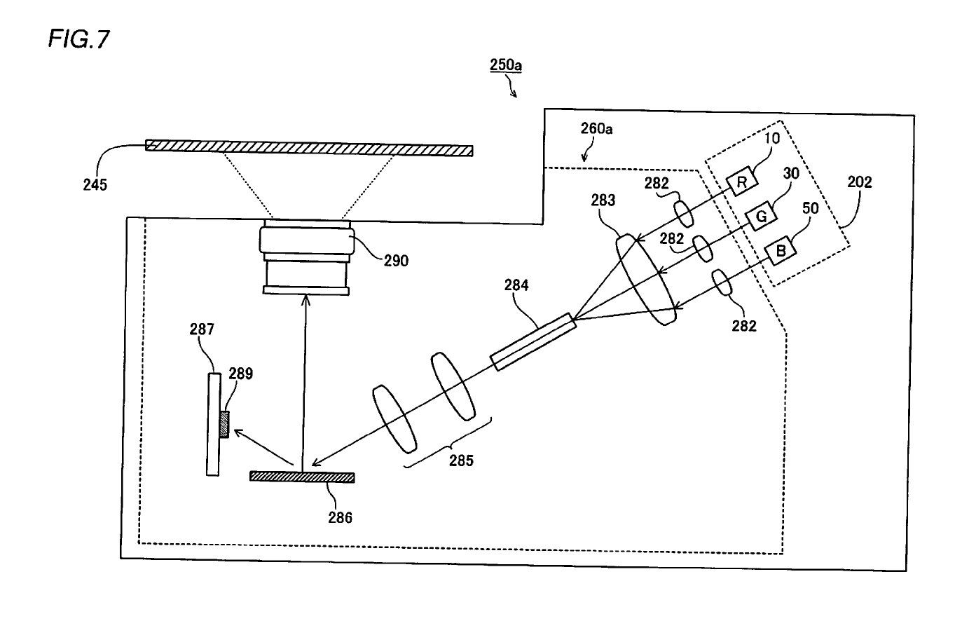

In a projector 250a shown in FIG. 7, a light source portion 202 is formed by arraying a red semiconductor laser element 10, a green semiconductor laser element 30 and a blue semiconductor laser element 50 provided in packages separate from each other, similarly to the light source portion 201 in the projector 200a shown in FIG. 5. An optical system 260a is so formed that beams transmitted through respective lenses 282 provided for light sources of red, green and blue are condensed by a condenser lens 283 and thereafter introduced into a light pipe 284, dissimilarly to the optical system 260 shown in FIG. 4. The remaining structure of the optical system 260a is similar to that shown in FIG. 4. The laser beams emitted from the semiconductor laser elements 10, 30 and 50 are modulated by the optical system 260a, and thereafter projected on a screen 245. The projector 250a is an example of the “display” in the present invention, and the optical system 260a is an example of the “modulation means” in the present invention.

According to the second embodiment, as hereinabove described, the red, green and blue semiconductor laser elements 10, 30 and 50 are provided in the packages separate from each other, whereby the optical system 211 (260a) can be simplified also when the optical system 211 or 260a including the light sources of red, green and blue having different optical paths is formed in the projector 200b or 250a. Thus, the degree of freedom in design of the optical system 211 or 260a in the projector 200b or 250a can be improved.

### Third Embodiment

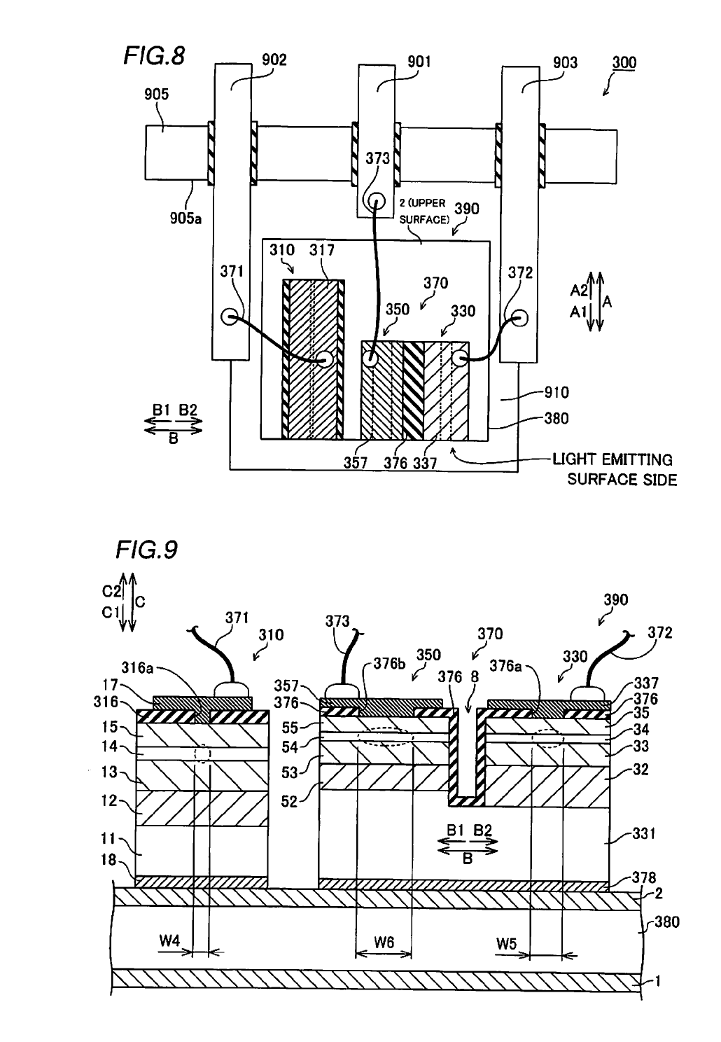

A third embodiment of the present invention is described with reference to FIGS. 8 and 9. In a semiconductor light-emitting device 300 according to the third embodiment, an RGB triple-wavelength semiconductor laser element portion 390 is formed by arranging a red semiconductor laser element 310 and a monolithic double-wavelength semiconductor laser element portion 370 consisting of a green semiconductor laser element 330 and a blue semiconductor laser element 350 on a base 380, dissimilarly to the aforementioned first embodiment. According to the third embodiment, a gain-guided semiconductor laser element prepared by forming a current blocking layer having a striped opening extending along a cavity direction on a planar upper cladding layer (p-type cladding layer) is applied to each of the red, green and blue semiconductor laser elements 310, 330 and 350. The red semiconductor laser element 310, the green semiconductor laser element 330 and the blue semiconductor laser element 350 are examples of the “red semiconductor light-emitting element”, the “green semiconductor light-emitting element” and the “blue semiconductor light-emitting element” in the present invention respectively.

In the semiconductor light-emitting device 300 according to the third embodiment of the present invention, the RGB triple-wavelength semiconductor laser element portion 390 is fixed onto the upper surface of a protruding block 910, as shown in FIG. 8. In the semiconductor light-emitting device 300, the red semiconductor laser element 310 having an oscillation wavelength of about 635 nm and the double-wavelength semiconductor laser element portion 370 formed by integrating the green semiconductor laser element 330 having an oscillation wavelength of about 530 nm and the blue semiconductor laser element 350 having an oscillation wavelength of about 480 nm on a common n-type GaN substrate 331 are fixed onto the upper surface of a base 380 at a prescribed interval through a conductive adhesive layer 2 of AuSn solder or the like. The cavity length (in a direction A) of the red semiconductor laser element 310 is rendered larger than that of the double-wavelength semiconductor laser element portion 370.

The RGB triple-wavelength semiconductor laser element portion 390 is so formed that output power ratios of the aforementioned red, green and blue semiconductor laser elements 310, 330 and 350 of 635 nm, 530 nm and 480 nm are adjusted to about 9.2:about 8.1:about 16.7 in terms of watts, for obtaining with light. In other words, the red semiconductor laser element 310, the green semiconductor laser element 330 and the blue semiconductor laser element 350 are so formed as to have rated output powers of about 900 mW, about 800 mW and about 1700 mW respectively according to the third embodiment.

According to the third embodiment, the red semiconductor laser element 310 is so formed that a waveguide (region surrounded by a broken line in FIG. 9) formed in a semiconductor element layer (portion of an active layer 14) has a width W4 of about 3 μm while the waveguides (regions surrounded by broken lines) of the green semiconductor laser element 330 and the blue semiconductor laser elements 350 have a width W5 of about 20 μm and a width W6 of about 30 μm respectively, as shown in FIG. 9. In other words, the widths (W5 and W6) of the waveguides in the green semiconductor laser element 330 and the blue semiconductor laser element 350 having the short oscillation wavelengths are rendered larger than the width W4 of the waveguide of the red semiconductor laser element 310 (W4<W5 and W4<W6).

In the red semiconductor laser element 310, a current blocking layer 316 made of SiO₂ is formed on the surface of a planar p-type cladding layer 15 while leaving an opening 316a forming a current path and extending in the direction A in a striped manner, as shown in FIG. 9. The opening 316a forms the waveguide having the width W4 (about 3 μm) in the portion of the active layer 14.

In the green semiconductor laser element 330 and the blue semiconductor laser element 350, current blocking layers 376 are formed on the surfaces of planar p-type cladding layers 35 and 55 while leaving openings 376a and 376b extending in the direction A in a striped manner respectively, as shown in FIG. 9. The opening 376a forms the waveguide having the width W5 (about 20 μm) in a portion of an active layer 34, while the opening 376b forms the waveguide having the width W6 (about 30 μm) in a portion of an active layer 54.

In the gain-guided semiconductor laser elements 310, 330 and 350 of the semiconductor light-emitting device 300 according to the third embodiment, the widths of the openings (316a, 376a and 376b) provided in the current blocking layers (316 and 376) of the respective semiconductor laser elements 310, 330 and 350 correspond to the widths (W4, W5 and W6) of the waveguides of the respective semiconductor laser elements 310, 330 and 350.

A p-side pad electrode 337 is formed on the current blocking layer 376 of the green semiconductor laser element 330 while a p-side pad electrode 357 is formed on the current blocking layer 376 of the blue semiconductor laser element 350, as shown in FIG. 9. An n-side electrode 378 constituted of a Ti layer, a Pt layer and an Au layer successively stacked from the side closer to the n-type GaN substrate 331 is formed on the lower surface of the n-type GaN substrate 331.

As shown in FIG. 8, the red semiconductor laser element 310 is arranged on the B1 side of the base 380, while the double-wavelength semiconductor laser element portion 370 is arranged on the B2 side.

The red semiconductor laser element 310 is connected to a lead terminal 902 through a metal wire 371 bonded to the p-side pad electrode 317. The green semiconductor laser element 330 of the double-wavelength semiconductor laser element portion 370 is connected to a lead terminal 903 through a metal wire 372 bonded to the p-side pad electrode 337. The blue semiconductor laser element 350 is connected to a lead terminal 901 through a metal wire 373 bonded to the p-side pad electrode 357. The remaining structure of the semiconductor light-emitting device 300 according to the third embodiment is similar to that of the aforementioned first embodiment.

A manufacturing process for the semiconductor light-emitting device 300 according to the third embodiment is now described with reference to FIGS. 8 and 9.

In the manufacturing process for the semiconductor light-emitting device 300 according to the third embodiment, an n-type GaN layer 52, an n-type cladding layer 53, the active layer 54 and a p-type cladding layer 55 for constituting the blue semiconductor laser element 350 are successively formed on the upper surface of the n-type GaN substrate 331, as shown in FIG. 9. Thereafter the n-type GaN substrate 331 is partly exposed by partly etching the n-type GaN layer 52, the n-type cladding layer 53, the active layer 54 and the p-type cladding layer 55, and an n-type GaN layer 32, an n-type cladding layer 33, the active layer 34 and a p-type cladding layer 35 for constituting the green semiconductor laser element 330 are successively formed on part of the exposed portion while leaving a region for forming a recess portion 8. Thereafter the current blocking layers 376 are formed while leaving the openings 376a and 376b.

At this time, the opening 376a is so formed that the waveguide having the width W5 of about 20 μm is formed in the portion of the active layer 34 while the opening 376b is so formed that the waveguide having the width W6 of about 30 μm is formed in the portion of the active layer 34 according to the third embodiment.

Thereafter the p-side pad electrodes 337 and 357 are formed by vacuum evaporation, to fill up spaces above the current blocking layers 376 and the openings 376a and 376b. Thus, the blue semiconductor laser element 350 and the green semiconductor laser element 330 are prepared to be isolated from each other by the recess portion 8 whose bottom portion reaches the n-type GaN substrate 331 at a prescribed interval in a direction B.

Then, the lower surface of the n-type GaN substrate 331 is polished, and the n-side electrode 378 is thereafter formed on the lower surface of the n-type GaN substrate 331, thereby preparing a wafer of the double-wavelength semiconductor laser element portion 370. Thereafter the wafer is cleaved in the form of a bar to have a prescribed cavity length and divided (brought into a chip state) in a cavity direction, thereby forming a chip of the double-wavelength semiconductor laser element portion 370 (see FIG. 9).

A manufacturing process for the red semiconductor laser element 310 is similar to that for the red semiconductor laser element 10 in the aforementioned first embodiment, except for a step of forming the current blocking layer 316 on the upper surface of the p-type cladding layer 15 while leaving the opening 316a. At this time, the opening 316a is so formed on the upper surface of the p-type cladding layer 15 that the waveguide having the width W4 of about 3 μm is formed in the portion of the active layer 14 of the red semiconductor laser element 310.

Thereafter the RGB triple-wavelength semiconductor laser element portion 390 is formed by fixing the red semiconductor laser element 310 and the double-wavelength semiconductor laser element portion 370 to the base 380 through a conductive adhesive layer 2 of AuSn solder or the like while pressing the former against the latter, as shown in FIG. 8. The remaining manufacturing process for the semiconductor light-emitting device 300 according to the third embodiment is similar to that in the aforementioned second embodiment.

According to the third embodiment, as hereinabove described, the green semiconductor laser element 330 and the blue semiconductor laser element 350 are formed on the common n-type GaN substrate 331, whereby the width of the double-wavelength semiconductor laser element portion 370 including the green semiconductor laser element 330 and the blue semiconductor laser element 350 integrated on the common n-type GaN substrate 331 in the direction B can be reduced due to the integration, as compared with a case of forming the green semiconductor laser element 330 and the blue semiconductor laser element 350 on separate substrates and thereafter arranging the same in a package (on the base 380) at a prescribed interval. Thus, the double-wavelength semiconductor laser element portion 370 can be easily arranged in the package (on the base 380). The remaining effects of the third embodiment are similar to those of the aforementioned first embodiment.

### Fourth Embodiment

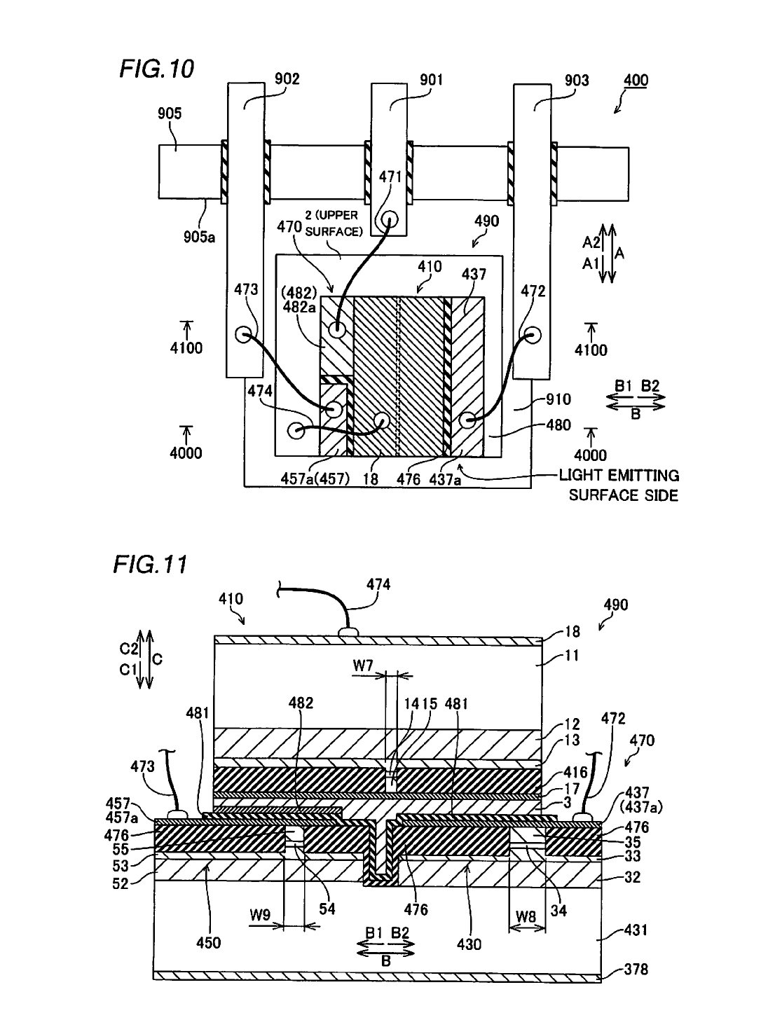

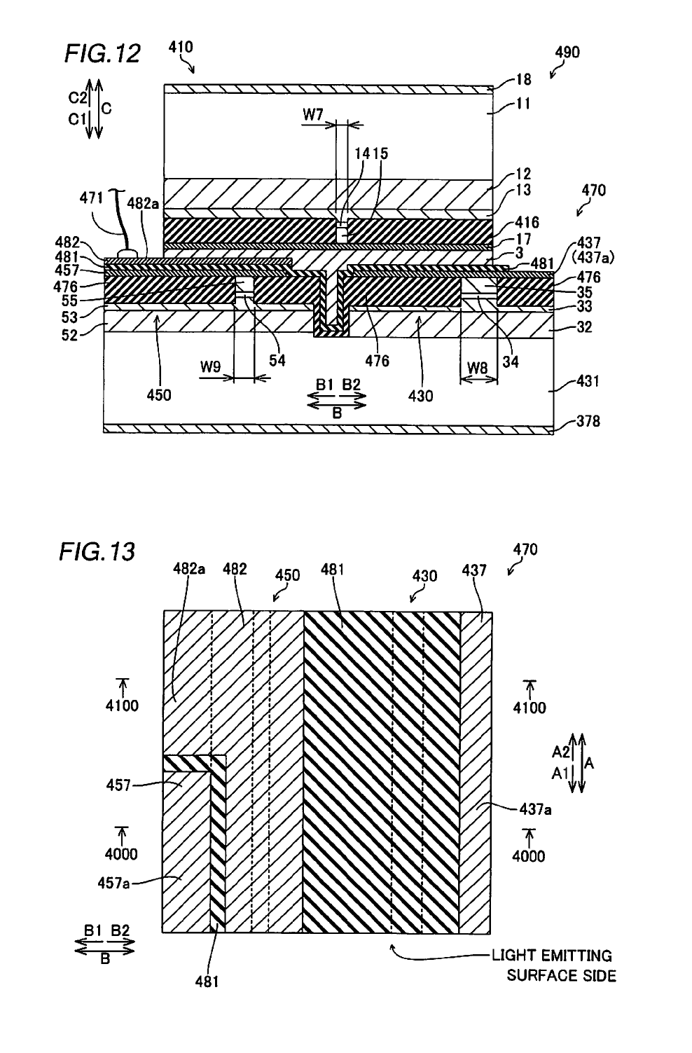

A fourth embodiment of the present invention is described with reference to FIGS. 10 to 13. In a semiconductor light-emitting device 400 according to the fourth embodiment of the present invention, an RGB triple-wavelength semiconductor laser element portion 490 is formed by bonding a red semiconductor laser element 410 onto the surface of a monolithic double-wavelength semiconductor laser element portion 470 emitting a green beam and a blue beam. According to the fourth embodiment, all of the red semiconductor laser element 410, a green semiconductor laser element 430 and a blue semiconductor laser element 450 are formed as semiconductor laser elements having BH structures. The red semiconductor laser element 410, the green semiconductor laser element 430 and the blue semiconductor laser element 450 are examples of the “red semiconductor light-emitting element”, the “green semiconductor light-emitting element” and the “blue semiconductor light-emitting element” in the present invention respectively. FIG. 11 shows a section taken along the line 4000-4000 in FIG. 10, and FIG. 12 shows a section taken along the line 4100-4100 in FIG. 1.

In the semiconductor light-emitting device 400 according to the fourth embodiment of the present invention, the RGB triple-wavelength semiconductor laser element portion 490 is fixed onto the upper surface of a protruding block 910, as shown in FIG. 10. In the RGB triple-wavelength semiconductor laser element portion 490, the red semiconductor laser element 410 having an oscillation wavelength of about 635 nm and the double-wavelength semiconductor laser element portion 470 formed by integrating the green semiconductor laser element 430 having an oscillation wavelength of about 520 nm and the blue semiconductor laser element 450 having an oscillation wavelength of about 460 nm on a common n-type GaN substrate 431 are fixed onto the upper surface of a base 480 through a conductive adhesive layer 2 of AuSn solder or the like at a prescribed interval. The red semiconductor laser element 410 and the double-wavelength semiconductor laser element portion 470 are so formed that the cavity lengths thereof are substantially identical to each other. Therefore, light emitting surfaces (A1 side in FIG. 10) and light reflecting surfaces (A2 side in FIG. 10) of the respective semiconductor laser elements 410, 430 and 450 are aligned with each other on the same planes.

The RGB triple-wavelength semiconductor laser element portion 490 is so formed that output power ratios of the aforementioned red, green and blue semiconductor laser elements 410, 430 and 450 of 635 nm, 520 nm and 460 nm are adjusted to about 24.5:about 9.9:about 7.2 in terms of watts respectively, for obtaining white light. In other words, the red semiconductor laser element 410, the green semiconductor laser element 430 and the blue semiconductor laser element 450 are so formed as to have rated output powers of about 2500 mW, about 1000 mW and about 700 mW respectively according to the fourth embodiment.

According to the fourth embodiment, the red semiconductor laser element 410 is so formed that a waveguide formed in a semiconductor element layer (portion of an active layer 14) has a width W7 of about 5 μm while waveguides of the green semiconductor laser element 430 and the blue semiconductor laser elements 450 have a width W8 of about 15 μm and a width W9 of about 10 μm respectively, as shown in FIG. 11. In other words, the widths (W8 and W9) of the waveguides in the green semiconductor laser element 430 and the blue semiconductor laser element 450 are rendered larger than the width W7 of the waveguide of the red semiconductor laser element 410 (W7<W8 and W7<W9).

In the semiconductor laser elements 410, 430 and 450 having the BH structures according to the fourth embodiment, the widths of the active layers (14, 34 and 54) of the semiconductor laser elements 410, 430 and 450 in a direction B correspond to the widths (W7, W8 and W9) of the waveguides of the semiconductor laser elements 410, 430 and 450 respectively.

In the RGB triple-wavelength semiconductor laser element portion 490, the red semiconductor laser element 410 is bonded through an insulating film 481 made of SiO₂ formed on the surface of the double-wavelength semiconductor laser element portion 470 and a conductive adhesive layer 3 made of AuSn solder or the like, as shown in FIG. 11. The RGB triple-wavelength semiconductor laser element portion 490 is arranged on a position slightly deviating to the B2 direction from a substantially central portion of the base 480 in the direction B, as shown in FIG. 10.

As shown in FIG. 13, the insulating film 481 is so formed as to expose a part on the A1 side (wire-bonded region 457a) of a p-side pad electrode 457 of the blue semiconductor laser element portion 450 and a part of a p-side pad electrode 437 of the green semiconductor laser element 430. An electrode layer 482 made of Au is formed on a prescribed region in the vicinity of an end portion on the A2 side of the blue semiconductor laser element 450, to cover the insulating film 481. Thus, a p-side pad electrode 417 of the red semiconductor laser element 410 is partly connected with the electrode layer 482 through the conductive adhesive layer 3 in a region opposed to the electrode layer 482 in a direction C, as shown in FIG. 12. The electrode layer 482 is so formed that an end region (wire-bonded region 482a) on the B1 side is exposed on a portion sideward from the red semiconductor laser element 410, as shown in FIG. 13.

As shown in FIG. 10, the red semiconductor laser element 410 is connected to a lead terminal 901 through a metal wire 471 bonded to the wire-bonded region 482a of the electrode layer 482. The green semiconductor laser element portion 430 (see FIG. 11) of the double-wavelength semiconductor laser element portion 470 is connected to a lead terminal 903 through a metal wire 472 bonded to the wire-bonded region 437a of the p-side pad electrode 437. The blue semiconductor laser element 450 (see FIG. 11) is connected to a lead terminal 902 through a metal wire 473 boned to the wire-bonded region 457a of the p-side pad electrode 457. The remaining structure of the semiconductor light-emitting device 400 according to the fourth embodiment is similar to that of the aforementioned third embodiment.

A manufacturing process for the semiconductor light-emitting device 400 according to the fourth embodiment is now described with reference to FIGS. 10, 11 and 13.

In the manufacturing process for the semiconductor light-emitting device 400 according to the fourth embodiment, the red semiconductor laser element 410 brought into a chip state and the double-wavelength semiconductor laser element portion 470 in a wafer state are prepared through steps similar to those in the aforementioned first and second embodiments respectively.

When dry etching is performed after stacking semiconductor layers for forming each of the semiconductor laser elements 410, 430 and 450 in the fourth embodiment, the etching started from a p-type cladding layer is progressed up to an intermediate portion of an n-type cladding layer. Thus, the active layer 14 is so formed that the waveguide having the width W7 (see FIG. 11) of about 5 μm is formed in formation of the red semiconductor laser element 410. In formation of the green and blue semiconductor laser elements 430 and 450, the active layers (34 and 54) thereof are so formed that the waveguides having the widths W8 and W9 (see FIG. 11) of about 15 μm and about 10 μm are formed respectively.

Therefore, current blocking layers 416 and 476 are so formed as to cover the upper surfaces of n-type cladding layers of the semiconductor laser elements 410, 430 and 450, the side surfaces of the active layers 14, 34 and 54 and those of p-type cladding layers respectively. Thereafter the p-side pad electrodes 417, 437 and 457 are formed on the current blocking layers 416 and 476 and portions of the p-type cladding layers not provided with the current blocking layers 416 and 476 by vacuum evaporation.

In subsequent formation of the double-wavelength semiconductor laser element portion 470, the insulating film 481 is so formed as to cover the upper surface of the current blocking layer 476 (see FIG. 12) while extending in a direction A and leaving the wire-bonded region 457a (B1 side) of the p-side pad electrode 457 and the wire-bonded region 437a (B2 side) of the p-side pad electrode 437, as shown in FIG. 13. Thereafter the electrode layer 482 having the wire-bonded region 482a is formed on a portion of the upper surface of the insulating film 481 excluding the p-side pad electrode 457 of the blue semiconductor laser element 450.

Then, the RGB triple-wavelength semiconductor laser element portion 490 in a wafer state is formed by bonding the wafer provided with the double-wavelength semiconductor laser element portion 470 and the red semiconductor laser element 410 to each other through the conductive adhesive layer 3 while opposing the same to each other, as shown in FIG. 11. Thereafter the wafer provided with the RGB triple-wavelength semiconductor laser element portion 490 is cleaved (in the form of a bar) to have a prescribed cavity length and divided (brought into a chip state) in the cavity direction, thereby forming a chip of the RGB triple-wavelength semiconductor laser element portion 490.

Thereafter the RGB triple-wavelength semiconductor laser element portion 490 is formed by fixing the same to the base 480 through a conductive adhesive layer (not shown) while pressing the former against the latter, as shown in FIG. 10. Thereafter the electrode layer 482 (wire-bonded region 482a) and the lead terminal 901 are connected with each other by the metal wire 471. Thus, the semiconductor light-emitting device 400 according to the fourth embodiment is formed.

According to the fourth embodiment, as hereinabove described, the p-side pad electrode 417 of the red semiconductor laser element 410 is bonded to a surface of the double-wavelength semiconductor laser element portion 470 opposite to the n-type GaN substrate 431 so that light-emitting portions of the semiconductor laser elements 410, 430 and 450 are rendered closer to each other in the transverse direction (direction B) due to the bonding between the red semiconductor laser element 410 and the double-wavelength semiconductor laser element portion 470 in the direction C as compared with a case of merely linearly arranging the red semiconductor laser element 410 and the double-wavelength semiconductor laser element portion 470 (transversely aligning the same on the base 480, for example), whereby light-emitting points of the semiconductor laser elements 410, 430 and 450 can be concentrated on a central region of a package (base 480). Further, the light-emitting points can be arranged to be close to each other in the thickness direction (direction C) of the semiconductor laser elements 410, 430 and 450. Thus, three laser beams emitted from the RGB triple-wavelength semiconductor laser element portion 490 can be concentrated on an optical axis of an optical system in a projector, whereby the semiconductor light-emitting device 400 and the optical system can be easily adjusted.

According to the fourth embodiment, the p-side pad electrode 417 of the red semiconductor laser element 410 is so bonded to the surface of the double-wavelength semiconductor laser element portion 470 opposite to the n-type GaN substrate 431 that no space is required for separately arranging (bonding) the red semiconductor laser element 410 on (to) the base 480 on which the double-wavelength semiconductor laser element portion 470 is not arranged, whereby the plane area of the base 480 can be reduced. Thus, the semiconductor laser elements 410, 430 and 450 can be easily arranged in the package.

According to the fourth embodiment, the waveguide of the red semiconductor laser element 410 is positioned over a region held between the waveguides of the green and blue semiconductor laser elements 430 and 450 in the direction B so that the all colors can be easily mixed with each other due to a red light-emitting point held between green and blue light-emitting points, whereby a uniform white light source can be obtained. The remaining effects of the fourth embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the red semiconductor laser element, the green semiconductor laser element and the blue semiconductor laser element are employed as the “red semiconductor light-emitting element”, the “green semiconductor light-emitting element” and the “blue semiconductor light-emitting element” in the present invention respectively in each of the aforementioned first to fourth embodiments, the present invention is not restricted to this. According to the present invention, a red superluminescent diode (SLD), a green SLD and a blue SLD may alternatively be employed as the red semiconductor light-emitting element, the green semiconductor light-emitting element and the blue semiconductor light-emitting element respectively. Further alternatively, one or two of the three semiconductor light-emitting elements may be formed by semiconductor laser elements, while the remaining two or one may be formed by an SLD.

While the waveguides (light-emitting point regions) of the red, green and blue semiconductor laser elements 10, 30 and 50 constituting the RGB triple-wavelength semiconductor laser element portion 90 have the widths W1 (about 5 μm), W2 (about 20 μm) and W3 (about 10 μm) respectively in the aforementioned first embodiment, the present invention is not restricted to this. According to the present invention, the widths W1, W2 and W3 of the waveguides may be so set as to satisfy the relations of W1<W2 and W1<W3. Also in each of the embodiments other than the aforementioned first embodiment, the widths of the waveguides of the red, green and blue semiconductor laser elements may be so set to have relations similar to the above, in place of the widths of the waveguides illustrated in each embodiment.

The relations between the rated output powers, the oscillation wavelengths and the widths of the waveguides of the semiconductor laser elements constituting the RGB triple-wavelength semiconductor laser element portion in each of the aforementioned first to fourth embodiments may be applied to the RGB triple-wavelength semiconductor laser element portion in a different embodiment.

While the red semiconductor laser element 410 is bonded onto the monolithic double-wavelength semiconductor laser element portion 470 formed by integrating the green and blue semiconductor laser elements 430 and 450 in the aforementioned fourth embodiment, the present invention is not restricted to this. According to the present invention, the red semiconductor laser element 410 may alternatively be bonded onto the green semiconductor laser element 330 or the blue semiconductor laser element 410 according to the aforementioned third embodiment.

While the present invention is applied to the projector loaded with the semiconductor light-emitting device 100 emitting white light as an exemplary display in each of the aforementioned first and second embodiments, the present invention is not restricted to this. The present invention may alternatively be applied to a display such as a rear projection television or a liquid crystal display, for example, other than the projector so far as the same is loaded with the semiconductor light-emitting device 100 emitting white light.

While the semiconductor laser elements are formed by the broad stripe semiconductor laser elements in each of the aforementioned first to fourth embodiments, the present invention is not restricted to this. According to the present invention, a green or blue laser element having a short wavelength may be formed by a broad stripe semiconductor laser element, while a red laser element having a long wavelength may be formed by a semiconductor laser element operating in transverse fundamental mode, for example. Also according to this structure, ideal white light can be easily realized.

While the base (80, 380 or 480) to which the RGB triple-wavelength semiconductor laser element portion is bonded is formed by a substrate made of AlN in each of the aforementioned first to fourth embodiments, the present invention is not restricted to this. According to the present invention, the base may alternatively be prepared from a conductive material consisting of Fe or Cu having excellent thermal conductivity.

While the red, green and blue semiconductor light-emitting elements constituting the semiconductor light-emitting device are formed by the same types of semiconductor laser elements in each of the aforementioned first to fourth embodiments, the present invention is not restricted to this. In other words, a semiconductor light-emitting device may be constituted of a ridge-guided semiconductor laser element, a gain-guided semiconductor laser element and a semiconductor laser element having a BH structure in a mixed state.

What is claimed is:

1. A light-emitting device comprising:
a waveguide-type red semiconductor light-emitting element emitting a red beam;
a waveguide-type green semiconductor light-emitting element emitting a green beam; and
a waveguide-type blue semiconductor light-emitting element emitting a blue beam, wherein
the width of a waveguide of said semiconductor light-emitting element emitting a beam of a relatively short wavelength is rendered larger than the width of a waveguide of said semiconductor light-emitting element emitting a beam of a relatively long wavelength in at least two semiconductor light-emitting elements among said red semiconductor light-emitting element, said green semiconductor light-emitting element and said blue semiconductor light-emitting element.

2. The light-emitting device according to claim 1, wherein
an output power of said semiconductor light-emitting element emitting said beam of said relatively short wavelength is smaller than an output power of said semiconductor light-emitting element emitting said beam of said relatively long wavelength.

3. The light-emitting device according to claim 1, wherein
the width of said waveguide of said green semiconductor light-emitting element is rendered larger than the width of said waveguide of said red semiconductor light-emitting element.

4. The light-emitting device according to claim 1, wherein
the width of said waveguide of said blue semiconductor light-emitting element is rendered larger than the width of said waveguide of said red semiconductor light-emitting element.

5. The light-emitting device according to claim 1, wherein
the widths of said waveguides of both of said green semiconductor light-emitting element and said blue semiconductor light-emitting element are rendered larger than the width of said waveguide of said red semiconductor light-emitting element.

6. The light-emitting device according to claim 1, wherein
at least one semiconductor light-emitting element among said red semiconductor light-emitting element, said green semiconductor light-emitting element and said blue semiconductor light-emitting element is a ridge-guided semiconductor laser element including a ridge provided on an upper layer on an active layer thereof for constituting said waveguide.

7. The light-emitting device according to claim 1, wherein
said two semiconductor light-emitting elements are ridge-guided semiconductor laser elements including ridges provided on upper layers on active layers thereof for constituting said waveguides, and
the width of a bottom portion, closer to said active layer, of said ridge of said semiconductor light-emitting element emitting said beam of said relatively short wavelength is rendered larger than the width of a bottom portion, closer to said active layer, of said ridge of said semiconductor light-emitting element emitting said beam of said relatively long wavelength.

8. The light-emitting device according to claim 1, wherein
at least one semiconductor light-emitting element among said red semiconductor light-emitting element, said green semiconductor light-emitting element and said blue semiconductor light-emitting element is a semiconductor laser element including a current blocking layer, having an opening, provided on the surface of a semiconductor element layer formed on an active layer thereof.

9. The light-emitting device according to claim 1, wherein
said two semiconductor light-emitting elements are semiconductor laser elements including current blocking layers, having openings, provided on the surfaces of semiconductor element layers formed on active layers thereof, and
the width of said opening of said current blocking layer of said semiconductor light-emitting element emitting said beam of said relatively short wavelength is rendered larger than the width of said opening of said current blocking layer of said semiconductor light-emitting element emitting said beam of said relatively long wavelength in said two semiconductor light-emitting elements.

10. The light-emitting device according to claim 1, wherein
at least one semiconductor light-emitting element among said red semiconductor light-emitting element, said green semiconductor light-emitting element and said blue semiconductor light-emitting element is a semiconductor laser element having a buried heterostructure whose active layer is held between current blocking layers formed on both side surfaces of said active layer.

11. The light-emitting device according to claim 1, wherein
said two semiconductor light-emitting elements are semiconductor laser elements having buried heterostructures whose active layers are held between current blocking layers formed on both side surfaces of said active layers, and
the width of said active layer of said semiconductor light-emitting element emitting said beam of said relatively short wavelength is rendered larger than the width of said active layer of said semiconductor light-emitting element emitting said beam of said relatively long wavelength in said two semiconductor light-emitting elements.

12. The light-emitting device according to claim 1, wherein
said red semiconductor light-emitting element, said green semiconductor light-emitting element and said blue semiconductor light-emitting element are arranged in a common package.

13. The light-emitting device according to claim 1, wherein
said green semiconductor light-emitting element and said blue semiconductor light-emitting element are formed on the surface of a substrate common to said green semiconductor light-emitting element and said blue semiconductor light-emitting element.

14. The light-emitting device according to claim 1, wherein
said red semiconductor light-emitting element is bonded to at least either said green semiconductor light-emitting element or said blue semiconductor light-emitting element.

15. The light-emitting device according to claim 14, wherein
at least either said green semiconductor light-emitting element or said blue semiconductor light-emitting element has an active layer on a substrate, and
said red semiconductor light-emitting element is bonded to said active-layer side of at least either said green semiconductor light-emitting element or said blue semiconductor light-emitting element.

16. The light-emitting device according to claim 1, wherein
at least one semiconductor light-emitting element among said red semiconductor light-emitting element, said green semiconductor light-emitting element and said blue semiconductor light-emitting element is a semiconductor laser element operating in transverse multimode.

17. The light-emitting device according to claim 16, wherein
said green semiconductor light-emitting element and said blue semiconductor light-emitting element are semiconductor laser elements operating in transverse multimode, and said red semiconductor light-emitting element is a semiconductor laser element operating in transverse fundamental mode.

18. The light-emitting device according to claim 1, wherein
the cavity length of said red semiconductor light-emitting element is larger than the cavity length of at least either said green semiconductor light-emitting element or said blue semiconductor light-emitting element.

19. A display comprising:
a light source, including a waveguide-type red semiconductor light-emitting element emitting a red beam, a waveguide-type green semiconductor light-emitting element emitting a green beam and a waveguide-type blue semiconductor light-emitting element emitting a blue beam, so formed that the width of a waveguide of said semiconductor light-emitting element emitting a beam of a relatively short wavelength is rendered larger than the width of a waveguide of said semiconductor light-emitting element emitting a beam of a relatively long wavelength in at least two semiconductor light-emitting elements among said red semiconductor light-emitting element, said green semiconductor light-emitting element and said blue semiconductor light-emitting element; and
modulation means modulating said beams emitted from said light source.

20. The display according to claim 19, wherein
at least two semiconductor light-emitting elements among said red semiconductor light-emitting element, said green semiconductor light-emitting element and said blue semiconductor light-emitting element are arranged in packages separate from each other.
